(19) United States
(12) Patent Application Publication
(10) Pub. No.: US 2015/0179863 A1
(43) Pub. Date: Jun. 25, 2015

(54) AVALANCHE PHOTODIODE UTILIZING INTERFACIAL MISFIT ARRAY

(71) Applicants: The Regents of the University of California, Oakland, CA (US); Lancaster University Business Enterprises LTD, Lancaster (GB)

(72) Inventors: Diana L. Huffaker, Los Angeles, CA (US); Charles J. Reyner, Mason, OH (US); Adam P. Craig, Lancaster (GB); Andrew R. J. Marshall, Lancaster (GB)

(21) Appl. No.: 14/577,927

(22) Filed: Dec. 19, 2014

Related U.S. Application Data
(60) Provisional application No. 61/919,619, filed on Dec. 20, 2013.

(51) Int. Cl. H01L 31/115; H01L 31/0304; H01L 31/18; H01L 31/107

(52) U.S. Cl. CPC H01L 31/115; H01L 31/1075; H01L 31/03046; H01L 31/03042; H01L 31/1844

(57) ABSTRACT

According to some embodiments of the present invention, an avalanche photodiode includes a first electrode, a second electrode spaced apart from the first electrode, a photon absorber layer formed to be in electrical connection with the first electrode, and a charge-carrier multiplication layer formed to be in electrical connection with the second electrode. The photon absorber layer is a semiconducting material that has a first lattice constant, and the charge-carrier multiplication layer is a semiconducting material that has a second lattice constant that is different from the first lattice constant. The photon absorber layer and the charge-carrier multiplication layer are connected together by an interfacial misfit (IMF) array at an interface thereof such that the IMF array provides at least part of an acceleration potential for an avalanche region of the avalanche photodiode.

This application claims priority to U.S. Provisional Application No. 61/919,619 filed Dec. 20, 2013, the entire content of which is hereby incorporated by reference.

This invention was made with Government support under Grant No. N00244-09-1-0091, awarded by the United States Department of Defense. The Government has certain rights in this invention.

### BACKGROUND

1. Technical Field

The field of the currently claimed embodiments of this invention relates to photodiodes, and more particularly to an avalanche photodiode utilizing an interfacial misfit array.

2. Discussion of Related Art

Avalanche photodiodes (APDs) are known to have enhanced sensitivities compared with simple p-i-n photodiodes. At the same time, improved detectors for the short and mid-infrared spectral ranges, between 1.4-8 μm, are increasingly sought after for various applications including telecommunications, military hardware,^{[1]} gas sensing^{[2]} and night-vision equipment. Long-wavelength APDs could be suitable for these purposes, especially where low photon fluxes are present. However, further development is required to combine longer-wavelength operation with higher sensitivities and lower dark currents and noise.

### SUMMARY

According to some embodiments of the present invention, an avalanche photodiode includes a first electrode, a second electrode spaced apart from the first electrode, a photon absorber layer formed to be in electrical connection with the first electrode, and a charge-carrier multiplication layer formed to be in electrical connection with the second electrode. The photon absorber layer is a semiconducting material that has a first lattice constant, and the charge-carrier multiplication layer is a semiconducting material that has a second lattice constant that is different from the first lattice constant. The photon absorber layer and the charge-carrier multiplication layer are connected together by an interfacial misfit (IMF) array at an interface thereof such that the IMF array provides at least part of an acceleration potential for an avalanche region of the avalanche photodiode.

According to some embodiments of the present invention, a high energy or low energy photon gamma ray detector includes a first electrode, a second electrode spaced apart from the first electrode, a photon absorber layer formed to be in electrical connection with the first electrode, and a charge-carrier multiplication layer formed to be in electrical connection with the second electrode. The photon absorber layer is a semiconducting material that has a first lattice constant, and the charge-carrier multiplication layer is a semiconducting material that has a second lattice constant that is different from the first lattice constant. The photon absorber layer and the charge-carrier multiplication layer are connected together by an interfacial misfit (IMF) array at an interface thereof such that the IMF array provides at least part of an acceleration potential for an avalanche region of the avalanche photodiode.

According to some embodiments of the present invention, a method for forming an avalanche photodiode includes selecting a substrate, depositing a buffer layer on the substrate, depositing on the buffer layer a first contact and a charge-carrier multiplication layer, and forming on the charge-carrier multiplication layer an interfacial misfit (IMF) array. The method further includes depositing on the IMF array a photon absorber layer, and depositing on the photon absorber layer a second contact. The substrate, the buffer layer, and the charge-carrier multiplication layer have a first lattice constant, and the photon absorber layer has a second lattice constant that is different from the first lattice constant. The avalanche photodiode is formed in a single fabrication process.

### BRIEF DESCRIPTION OF THE DRAWINGS

Further objectives and advantages will become apparent from a consideration of the description, drawings, and examples.

FIG. 1 is a schematic illustration of an avalanche photodiode according to some embodiments of the current invention;

FIG. 2 is a schematic illustration of an avalanche photodiode according to some embodiments of the current invention;

FIG. 3 shows four current density versus bias curves of interest (the solid dark grey and dashed light grey, dark grey, and black lines);

FIG. 4 shows quantum efficiency versus applied bias for some values of delta doping in APDs;

FIG. 5 shows band alignment for GaSb and InAs, two materials that may be used for detecting x-rays and gamma rays;

FIG. 6 shows a cross-sectional schematic of an InAs APD;

FIG. 7 shows a cross-sectional schematic of a GaSb APD;

FIG. 8 shows a summary of basic material parameters for InAs and AlGaSb;

FIG. 9 shows a plot of multiplication versus excess noise factor for the AlGaAs and GaAs designs;

FIG. 10 shows a summary of parameters for the AlGaAs and GaAs designs;

FIG. 11A shows a cross-sectional schematic of the GaAs design;

FIG. 11B shows a cross-sectional schematic of the AlGaAs design;

FIG. 12 shows IV data for 200 μm diameter mesas according to an embodiment of the invention;

FIG. 13 shows 300K spectral response curves for the GaAs design and the AlGaAs design;

FIG. 14 shows measured (solid line) and modeled (dashed line) CV data, as used to model multiplication;

FIG. 15 shows the calculation of the multiplication for 200 μm diameter mesas;

FIG. 16 shows data collected for the GaAs design, which lies in the range 0.2<k_{eff}<0.4; previously reported results for thin GaAs p-i-n diodes are also shown;

FIG. 17 shows data collected for the AlGaAs design according to an embodiment of the invention;

FIG. 18 illustrates how the devices described herein employ a novel integration of high atomic number (Z), small bandgap semiconductor absorbers (GaSb or InAsSb) with a low Z, large bandgap junction material ((Al)GaAs);

FIG. 19 shows energy gaps and lattice constants for a variety of materials;

FIG. 20 shows how the theoretical energy resolution of the device is similar to cryogenically cooled HPGe across all photon energies (or more specifically ˜0.14% at 662 keV) and outperforms other competing technologies;

FIG. 21 shows bandgaps and band offsets for materials at 300 K;

FIG. 22 shows a comparison of gamma ray detectors with high and low energy resolution (HPGe and NaI respectively);^{[24]}

FIG. 23 gives a summary of basic material parameters illustrating the relative merits of high and low Z materials for different parts of a gamma ray detector;

FIG. 24 shows photon absorption in selected semiconductor materials at the high energy range important for C-WMD;

FIG. 25 shows a schematic of an IMF array between layers of GaSb and GaAs;

FIG. 26A is an electron microscope image of a GaSb/GaAs interface with an IMF dislocation array (white dots);^{[25]}

FIG. 26B shows an 0044 x-ray diffraction scan of a GaSb/GaAs IMF sample;

FIG. 26C shows the peak responsivity of an IMF-based quaternary Ga_{0.82}In_{0.18}As_{0.16}Sb_{0.84}/GaAs photodiode at 0V and −0.2 V;

FIG. 27 shows an 0044 x-ray diffraction scan of a GaSb/GaAs IMF sample with varying GaSb thickness;

FIG. 28 shows peak power versus injection current for room temperature operation of a 1.65 μm laser on GaAs substrate;

FIG. 29 shows spurious signal in AlGaAs/GaAs APD detection of a 5.9 keV photon source;^{[27]} and

FIG. 30 shows improvements by year in energy resolution for a 59.5 keV photon.

### DETAILED DESCRIPTION

Some embodiments of the current invention are discussed in detail below. In describing embodiments, specific terminology is employed for the sake of clarity. However, the invention is not intended to be limited to the specific terminology so selected. A person skilled in the relevant art will recognize that other equivalent components can be employed and other methods developed without departing from the broad concepts of the current invention. All references cited anywhere in this specification, including the Background and Detailed Description sections, are incorporated by reference as if each had been individually incorporated.

Some embodiments of the current invention are directed to a novel architecture of low-noise amplification of an optical signal. It can allow one to mate a very noisy absorber material such as, but not limited to, GaSb or similar materials, to a low-noise multiplication region. Some embodiments of the current invention allow one to utilize the innate properties of an engineered defect structure to create avalanche gain, or to use a high degree of doping near the interface to allow multiplication to take place. Some embodiments of the current invention can have applications to infrared, x-ray and/or gamma ray photon detection. This can include, but is not limited to, applications for single photon detection, high speed detection, gas sensing, LADAR, and optical communications, for example.

Some embodiments of the current invention create optical absorption and signal multiplication in semiconductors of different lattice constants. The interface between the materials can be used according to some embodiments of the current invention to improve the signal-to-noise ratio in the photodiode, either through the electronic states at the interface, or through doping near the interface. Some embodiments of the current invention can substantially decrease the complexity of conventional devices, while increasing the signal-to-noise ratio.

Some embodiments of the current invention can use epitaxial deposition of GaSb on GaAs.^{[8]} The GaSb/GaAs interface forms a highly doped sheet of acceptors that act as the equivalent of a charge sheet of conventional avalanche photodiodes (APDs). A low k multiplication region is formed by deposition of an n-type cladding and a p-type cladding. An intrinsic multiplication region is optional. The p-type cladding may be comprised of a bulk material or may include the GaSb/GaAs interface. Within a few tens of nanometers from the interface, an n-type delta modulation doped layer may be inserted to enhance fields at the interface and increase photocurrent collection. The absorber material may then be epitaxially deposited on the GaSb/GaAs interface and a p-type contact may be formed. The entire structure may be deposited on an n-type contact.

In some embodiments, a low k multiplication region, such as, but not limited to, AlGaAs, can be integrated to a GaSb-based absorber region using the interface as a charge sheet and the delta-doping to reduce the field at the interface. Further enhancements can include longer wavelength absorbers (InAsSb), absorber grading regions (InGaAsSb), and multiplication grading (AlGaAs) to enhance photocurrent collection efficiency.

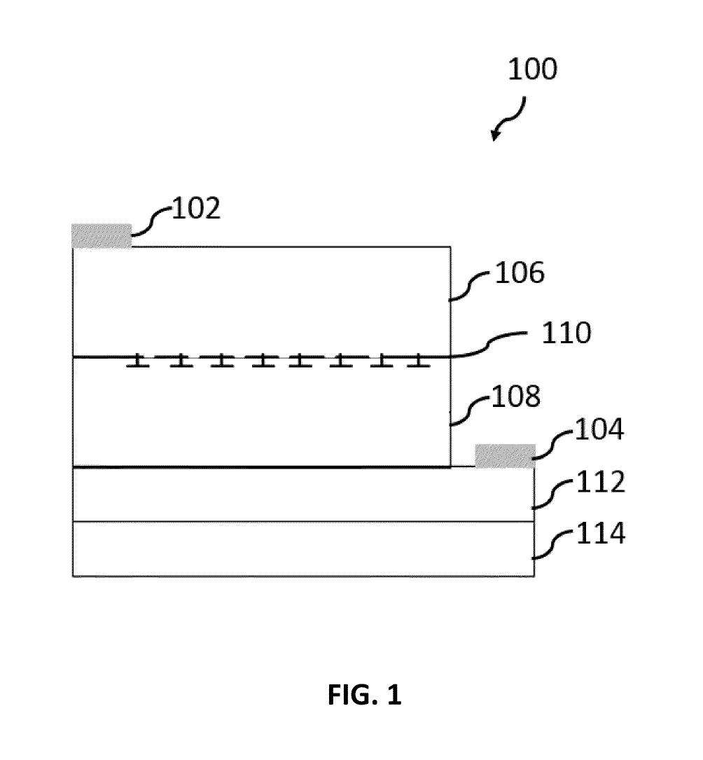

FIG. 1 is a schematic illustration of an avalanche photodiode 100 according to an embodiment of the current invention. The avalanche photodiode 100 includes a first electrode 102, a second electrode 104 spaced apart from the first electrode 102, a photon absorber layer 106 formed to be in electrical connection with the first electrode 102, and a charge-carrier multiplication layer 108 formed to be in electrical connection with the second electrode 104. The photon absorber layer 106 is a semiconducting material that has a first lattice constant, and the charge-carrier multiplication layer 108 is a semiconducting material that has a second lattice constant that is different from the first lattice constant. The photon absorber layer 106 and the charge-carrier multiplication layer 108 are connected together by an interfacial misfit (IMF) array 110. The IMF array provides at least part of an acceleration potential for an avalanche region of the avalanche photodiode.

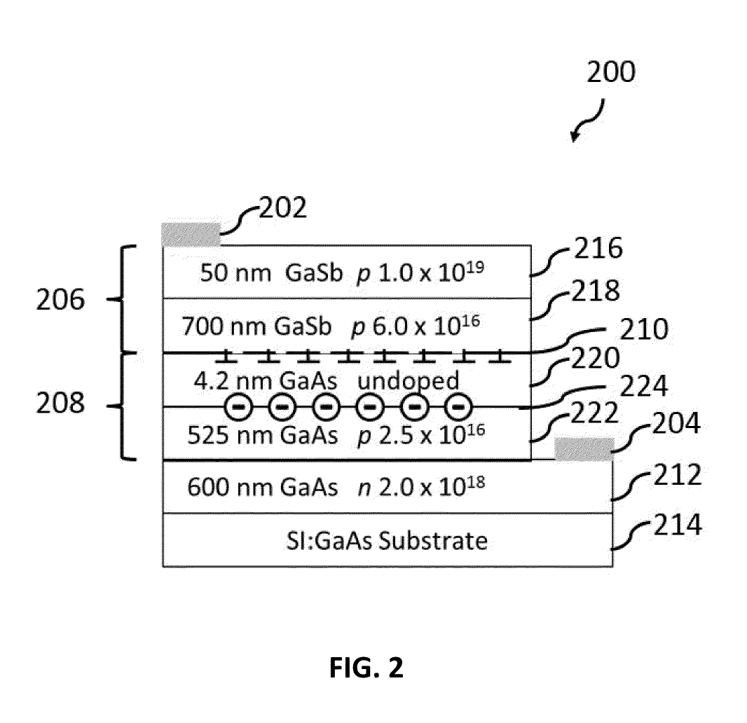

FIG. 2 is a schematic illustration of an avalanche photodiode 200 according to some embodiments of the current invention. Like the avalanche photodiode 100 in FIG. 1, the avalanche photodiode 200 includes a first electrode 202, a second electrode 204 spaced apart from the first electrode 202, a photon absorber layer 206 formed to be in electrical connection with the first electrode 202, and a charge-carrier multiplication layer 208 formed to be in electrical connection with the second electrode 204. The photon absorber layer 206 and the charge-carrier multiplication layer 208 are connected together by an interfacial misfit (IMF) array 210. The avalanche photodiode 200 also includes an ohmic contact region 212 and a substrate 214.

In some embodiments, the photon absorption layer 206 includes an ohmic contact region 216 and an absorber region 218. The absorber region 218 is proximate the IMF array 210 and the ohmic contract region 216 is farther from the IMF array 210. The absorber region 218 may be an undoped or lightly doped (carrier concentration less than 5×10¹⁷ cm⁻³) material. The doping of the absorber region 218 may be graded doping. The ohmic contact region 216 can have a higher doping concentration than the absorber region 218. However, the general concepts of the current invention are not limited to this particular example. The photon absorber layer 106 can be a single layer or a plurality of layers with single or multiple materials, and/or single or multiple doping regions. According to some embodiments, the ohmic contact region 216 and the absorber region 218 are doped with a same type of charge carrier.

The charge-carrier multiplication layer 208 of the avalanche photodiode 200 may include a spacer region 220 proximate to the IMF array 210, and a multiplication region 222 farther from the IMF array 210. However, the general concepts of the current invention are not limited to this particular example. The multiplication layer 208 can be a single layer or a plurality of layers with single or multiple materials, and/or single or multiple doping regions. The term “doped” region can include p-doping and/or n-doping depending on the particular embodiment.

The spacer region 220 may be undoped or unintentionally doped. The spacer region 220 may have a thickness of a few tens of nanometers. The multiplication region 222 may be an unintentionally doped or lightly doped (carrier concentration less than 5×10¹⁷ cm⁻³) material. The charge-carrier multiplication layer 208 may have a delta doped region 224 to act in combination with the IMF array 210 to provide a field across the IMF array 210 that improves quantum efficiency. However, the doped region 224 is not required in all embodiments. In some embodiments, the IMF array 210 provides the accelerating potential. The IMF array 210 has a first two-dimensional charge density of a first polarity, and the delta doped region 224 has a second two-dimensional charge density of a second polarity. The delta doping region 224 has a maximum carrier concentration that is less than 25% of the carrier concentration of the IMF array 210. The distance between the delta doping region 224 and the IMF array 210 is less than 30 nm.

FIG. 2 shows exemplary values for the thickness and doping concentration of some of the layers. The layers are not limited to these values, and other thicknesses and doping concentrations may be employed.

The term “charge-carrier” is intended to include electrons in some embodiments, or holes in other embodiments. Detailed examples provided in this specification are for the case of electrons as the charge carriers. However, the broad concepts of the current invention are not limited to only electrons as the charge carriers. For example, but without limitation, devices based on InP can provide holes as the charge carriers.

In some embodiments, the multiplication layer 208 can include at least one of silicon, GaAs, AlGaAs (any ratio of Ga to Al), InP, InAlAs (lattice-matched to InP), or InAlGaAs, and the photon absorber layer 206 can include at least one of GaSb, InAsSb, InGaAsSb, or any In(x)Ga(1-x)As(y)Sb(1-y) material. The photon absorber layer comprises a material having a lattice constant that is 6-6.2 Å.

A difference between some embodiments of the scheme described herein and convention schemes for lattice-mismatched APDs is the use of the IMF as a dopant. An electrical measurement of the IMF array indicates that the IMF array has an electrically measured hole/acceptor density, or interface charge density, of approximately 1.8×10¹² cm⁻². APDs typically have high doping levels on either side of the multiplication region to prevent spreading of the junction's electric field, which increases the electric field strength enough to promote impact ionization, e.g. gain/avalanching. One of the APD designs according to an embodiment of the current invention explicitly avoids the use of a high p-type region and uses the IMF array as that high doping level. Without the IMF array's high interface charge density, the device would require much higher applied bias levels to create an avalanche, if it could even avalanche at all.

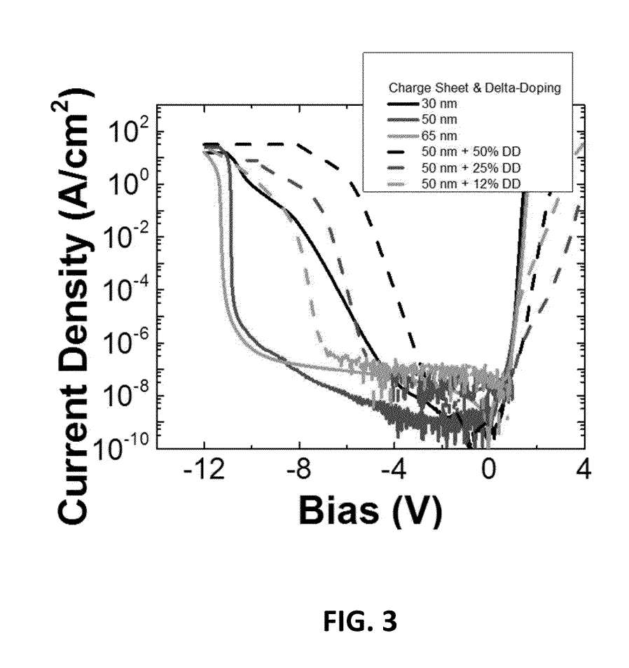

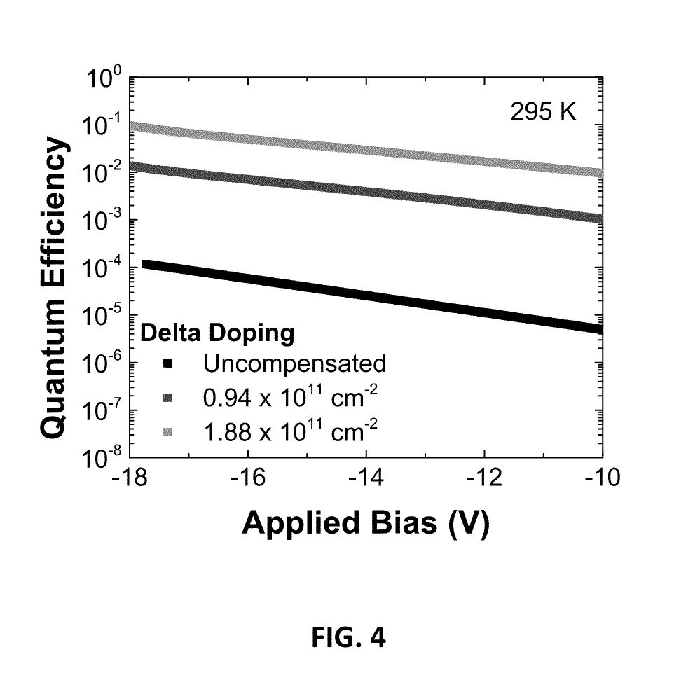

In some embodiments, electrons/donors were added near the IMF interface in the form of delta-doping using an AlGaAs multiplication region. There is an intrinsic field at the IMG interface because of the band alignments and the number of carriers, in this case holes. The delta doping changes this field, allowing more carriers (electrons in this case), to cross the IMF array. The values used for the charge density of the delta doped region were 1.5×10¹² cm⁻², 0.75×10¹² cm⁻², and 0.375×10¹² cm⁻², in addition to the value provided in the literature, 3×10¹² cm⁻². Data for these values can be seen in FIG. 3, along with a different experiment for “Charge Sheet”. FIG. 3 shows four current density versus bias curves of interest (the solid dark grey and dashed light grey, dark grey, and black lines). The photodiodes corresponding to the black and dark grey dashed lines are heavily delta-doped and do not function as APDs. They are just poorly-performing photodiodes with high dark currents. The low delta-doped photodiode does work as an APD, as does the 50 nm sample. It was counterintuitively found that values of 12% times the hypothesized interface charge density worked best for APD structures. The original thought, or what seemed obvious, was to use values closer to the actual interface charge. The design was improved in subsequent studies by looking only at the low delta-doping values. FIG. 4 shows quantum efficiency versus applied bias for additional values of delta doping in APDs having the structure shown in FIG. 2. The plot demonstrates how a small amount of delta doping initially increases the quantum efficiency by a factor of 100. Doubling that amount increases the efficiency by nearly an addition factor of 10. According to some embodiments, these remarkable improvements are the result of a delta-doping process that takes less than 120 seconds in a three hour device growth period. The delta doping may be a small fraction of an atomic layer, so the thickness of the APD is not changed and yet the device properties change dramatically.

The avalanche photodetectors according to some embodiments of the invention were constructed using molecular beam epitaxy (MBE), although metal-organic chemical vapor deposition (MOCVD) is also a possible deposition technique. First, a substrate that was lattice-matched to the multiplication region was chosen. Second, a buffer layer of the same material as the substrate was deposited. Following the buffer layer, the bottom contact, and multiplication region were deposited. At this point, the deposition rate slows as the optional delta-doping layer is formed, the undoped buffer before the IMF array is deposited, and the IMF array is formed. After forming the IMF array, the growth rate increases again with the introduction of either a buffer layer and the absorber, or simply the absorber. The final epitaxial step is the deposition of the top contact. The deposition rate during the entire process is typically from 0.1-0.3 nm/sec, except in the delta-doping and IMF array formation steps and any pauses to adjust cell or substrate temperatures. This value would most likely increase if MOCVD was the chosen deposition technique.

Following deposition, the wafers were fabricated into devices using standard III/V processing techniques. First, the top contact of Ti/Pt/Au was deposited using e-beam deposition. Following the top contact, mesa structures were formed using plasma etching, in this case BCl3/Ar. The final step was the deposition of the bottom AuGe/Ni/Au contact using e-beam deposition. All processing techniques used standard photolithography to define the features. This method is exemplary, and not all of the steps described above may be performed. Additionally, other materials than those described above may be used.

The avalanche photodiodes described herein have applications in high energy photon detection, short wave infrared detection (λ<1.7 μm), midwave infrared detection (λ<5 μm), longwave infrared detection, and terahertz detection (λ>30 μm). They also have applications in technologies requiring high bandwidth performance (bandwidths over 20 GHz and gains over 30), and in telecommunications, imaging, and LADAR, for example.

The following examples describe some embodiments in more detail. The broad concepts of the current invention are not intended to be limited to the particular examples.

### Examples

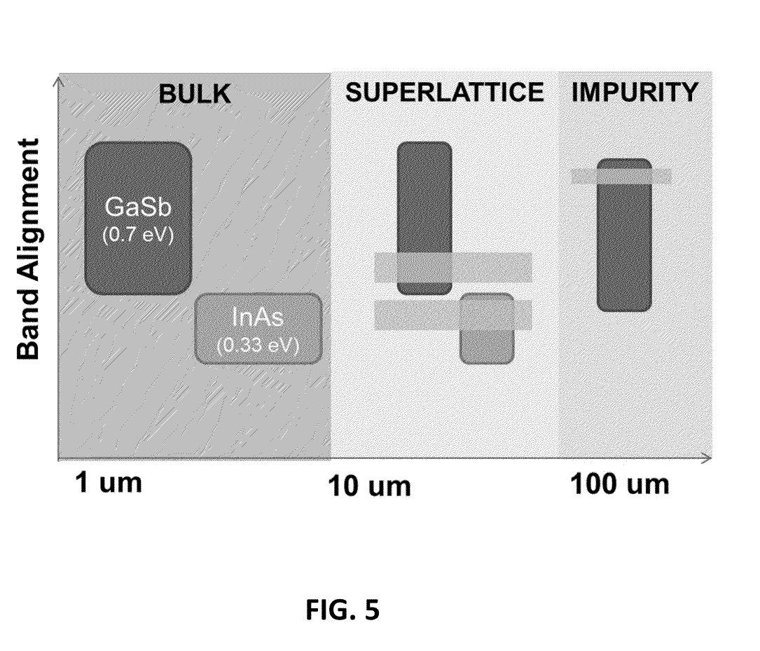

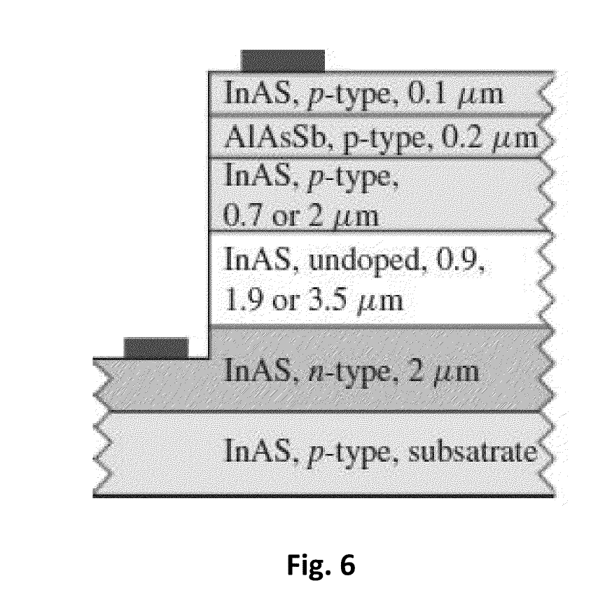

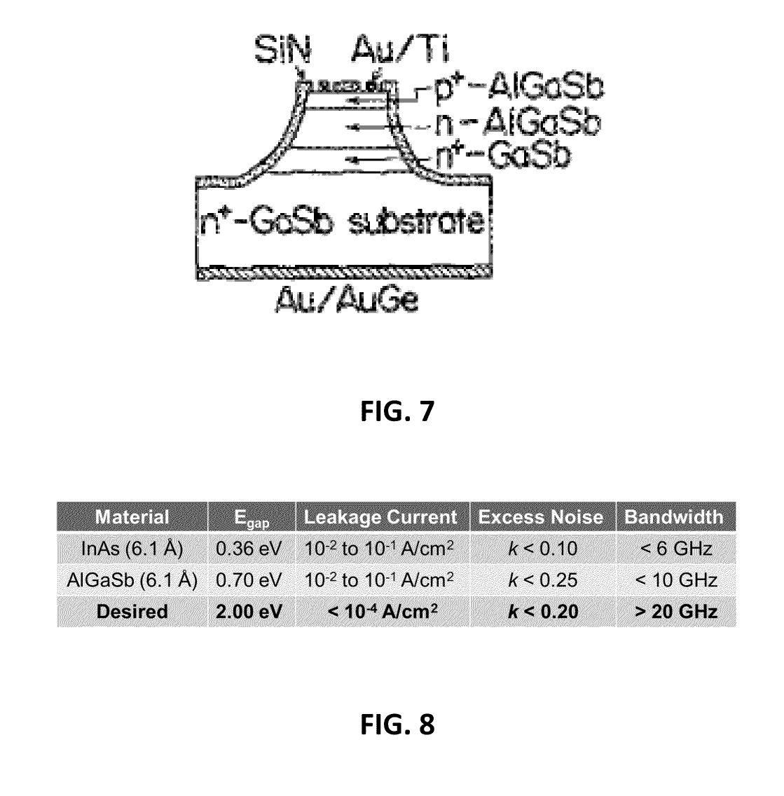

Designs based on GaSb and InAs substrates are an attractive choice for long-wavelength APDs, since a range of narrow-gap layers can then be grown lattice-matched. FIG. 5 shows band alignment for GaSb and InAs, which both have a 6.1 Å lattice constant. Lattice-matched layers in addition to binary GaSb and InAs include ternaries (e.g. InAsSb), quaternaries (e.g. InGaAsSb), and strained layer superlattices. Indeed, InAs APDs, like the one illustrated in FIG. 6, have a cut-off wavelength of 3.5 μm, and were recently shown to have very low avalanche noise.^{[3,3b]} However, they were also reported to suffer from significant surface-leakage currents and a potential for unwanted band-to-band tunneling effects. A schematic of a GaSb APD is shown in FIG. 7. FIG. 8 shows a summary of basic material parameters for InAs and AlGaSb, and demonstrates how both materials fall short of the desired properties. A high bandgap, low leakage junction is desirable.

One alternative approach is to use a strained-layer-superlattice for the multiplication region. This has been demonstrated on both GaSb and InP substrates, with reported cut-off wavelengths of 4.92 μm^{[4]} and 2.5 μm,^{[5]} respectively. Elsewhere, lattice matched InGaAsSb/AlGaAsSb separate-absorption-and-multiplication (SAM) structures have been developed. These have typically been grown on GaSb substrates, with cut-off wavelengths around 2.2 μm being reported.^{[6,7]} By taking advantage of both the absorption properties of a narrow-gap material and the multiplication properties of a wide-gap material, SAM-APD designs can offer an amalgam solution where long-wavelength devices with high sensitivities are required.

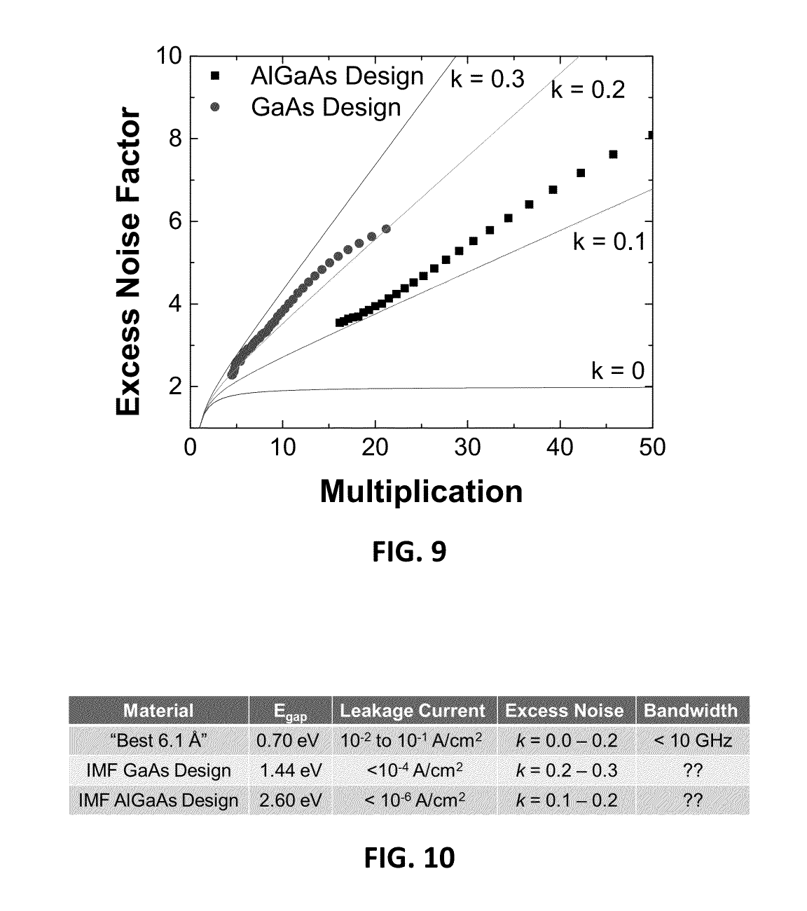

The interfacial misfit (IMF) array is a technique for molecular beam epitaxial (MBE) growth, allowing high-quality, relaxed epilayers to be deposited on lattice-mismatched substrates without the need for a metamorphic buffer.^{[8,9]} In this process, the strain is relieved within a few monolayers of the interface by a self-ordered network of 90° misfit dislocations, leaving intact the bulk properties of the deposited crystal. For the growth of GaSb onto GaAs in particular, derivative devices including light emitting diodes (LEDs)^{[10]} and lasers^{[11]} have already been demonstrated. In addition, recent publications include a report of GaInAsSb photodiodes, operating in the 2-2.4 μm wavelength range.^{[12]} These were reported to have a level of performance comparable with similar detectors grown on native GaSb substrates. In this work, IMF arrays are used to directly combine GaAs and AlGaAs multiplication layers (lattice constant 5.65 Å) with GaSb absorption layers (lattice constant 6.09 Å). FIG. 9 shows a plot of multiplication versus excess noise factor for the AlGaAs design and the GaAs design, and FIG. 10 shows a summary of parameters for the two designs. The GaAs design represents a proof-of-principle. This is developed in the AlGaAs design to realize lower excess noise, a thinner structure, and further suppression of the depletion currents. In both devices, a narrow-bandgap GaSb absorber material gives photocurrent at wavelengths up to 1.7 μm. Other absorber materials—specifically, those which are lattice-matched to GaSb—could also be used, allowing longer wavelength operation. This may be by using the IMF GaSb layer as a thin buffer.

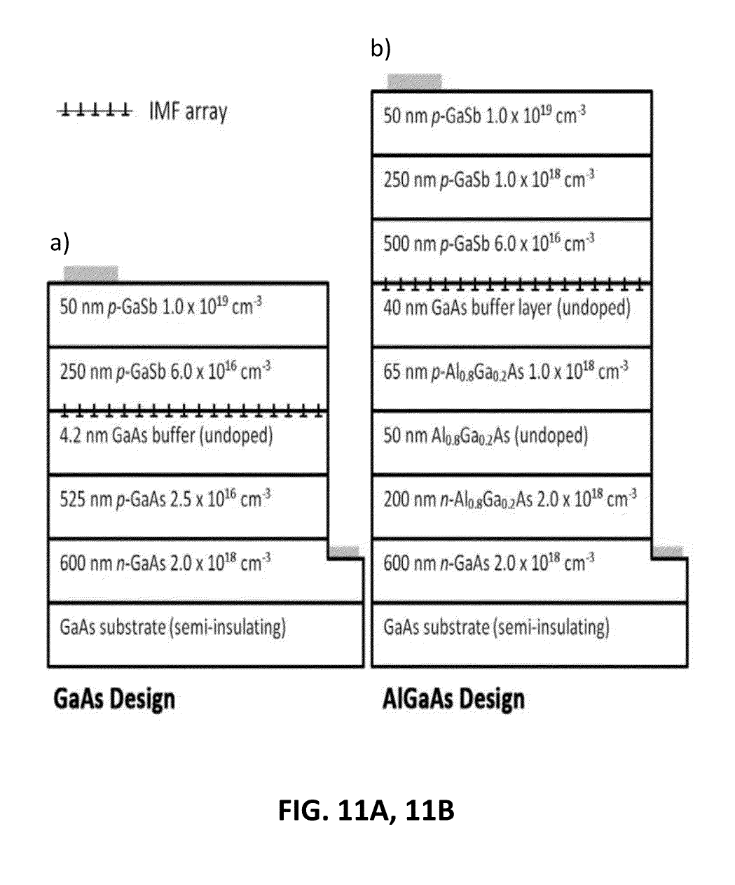

The GaAs and AlGaAs structures, which are depicted in FIGS. 11A and 11B, respectively, were grown using a Veeco Gen930 MBE reactor. In each case, oxide desorption from the GaAs substrate was performed first, at 600° C. The substrate temperature was subsequently reduced to 580° C. for the growth of the n⁺-GaAs cladding regions. For the GaAs design, a p⁻ multiplication region was grown next. In the AlGaAs design, this is replaced with a shorter, unintentionally doped multiplication region and a p⁺ charge sheet. The charge sheet strongly confines the high electric field within the multiplication region. Note that, for the GaAs design, the charge associated with the IMF array itself is sufficient to prevent the field spreading into the GaSb absorber.^{[13]} Growth then proceeded as follows for both samples. First, a short, undoped GaAs buffer was deposited. Next, after a brief interrupt with no applied As flux, which leaves the growth-surface Ga terminated, an Sb flux was applied in order to initiate the IMF interface. At the same time, the temperature was reduced to 510° C. Growth of the GaSb absorption and cap layers followed. The V-III ratios were approximately 10 for GaAs and AlGaAs growth and 4.2 for GaSb growth. All growth rates were between 0.2-1.0 MLs⁻¹. The n- and p-type dopants were Si and Be, respectively. Annular contacts were evaporated using Ti/Pt/Au for p-GaSb and AuGe/Ni/Au for n-GaAs. Circular mesas were defined using an inductively coupled plasma (ICP) reactive ion etch (RIE) and BCl3/Ar etch chemistry.

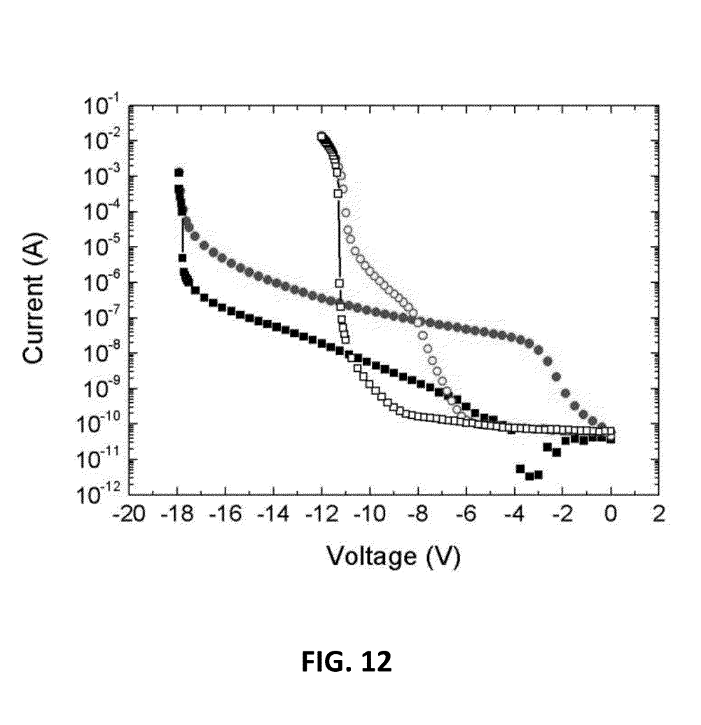

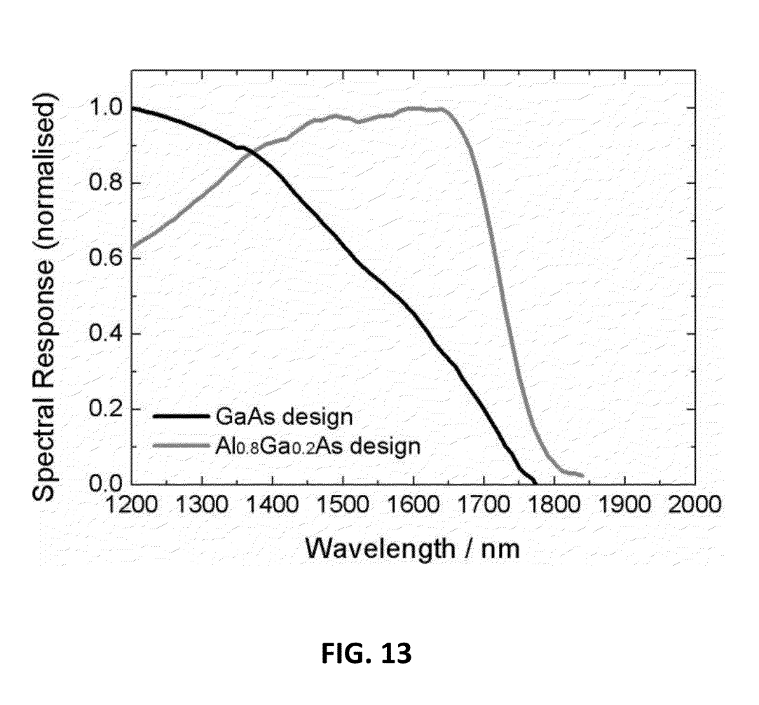

FIG. 12 shows detailed current-voltage (IV) data, collected using a Keithley 2400 SourceMeter. Illumination was provided by under-filling the device using a 15 mW 1.55 μm laser, incident via a cleaved, single-mode optical fiber. For both samples, the dark currents below breakdown were noted to be greatly reduced compared with levels expected for a homojunction GaSb p-i-n diode.^{[14]} This is attributed to the confinement of the electric field within the multiplication (wide-bandgap) regions, and remains true even after the onset of the 1.55 μm photocurrent. In turn, it is inferred that photogenerated carriers are able to travel from the GaSb absorption layers by diffusion, crossing the IMF interfaces. With 90% of breakdown voltage applied, current densities of 560 pAcm⁻² and 5.07 pAcm⁻² were noted, for the GaAs design and AlGaAs design, respectively. Conspicuous band-to-band tunneling effects were noted to be absent; these might have been expected if high fields were present in the GaSb regions. Furthermore, surface leakage currents, typically around 1×10⁻⁵ Acm⁻² at −5.0 V for 200 μm GaSb p-i-n diodes, grown and processed using the same procedures as the samples in the present work, were noted to have been suppressed. This is attributed to the wide-bandgap layers acting to increase the shunt resistance associated with the surface states. The multiplication was noted to be independent mesa area for both samples, showing that edge breakdown effects are absent, and thus do not influence the excess noise results presented here. FIG. 13 shows spectral response curves for both samples, taken at 300 K using a Stanford SR830 lock-in amplifier in combination with a Bentham TMc300 monochromator. By extrapolation of the squared response, plotted against energy, cut-off wavelengths of around 1.70 μm and around 1.75 μm were calculated, for the GaAs design and AlGaAs design, respectively. It should be noted that the cut-off wavelength is slightly increased in the AlGaAs design, owing to the thicker absorption region, which leads to a greater probability of absorption for longer-wavelength photons.

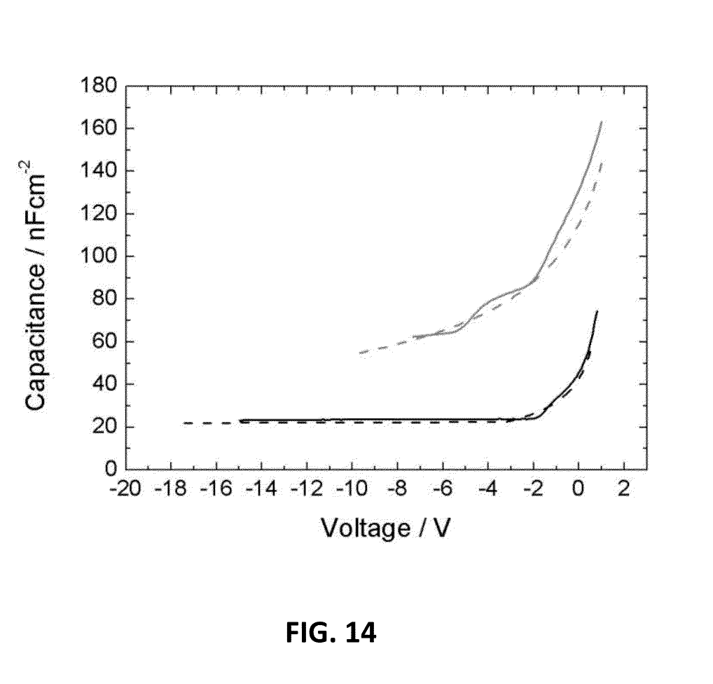

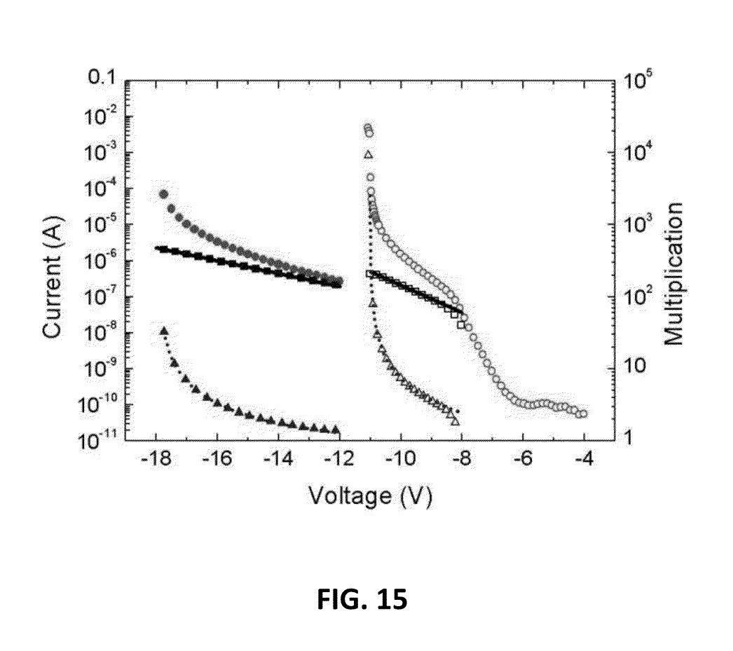

Extensive capacitance-voltage (CV) measurements were further taken for both samples, as illustrated in FIG. 14. Based upon a simple electrostatic model, close agreement was found with the nominal layer thicknesses and doping concentrations, which are given in FIGS. 11A and 11B, and the modeled curves are also shown in FIG. 14. It should be noted that the features in the experimental data for the AlGaAs design between approximately −2 V and −6 V result from charge redistribution due to the band offsets around the GaAs/AlGaAs heterointerface, although this is not accounted for in the modeled curve. The associated electric field profiles were next used to model multiplication, using standard integrals.^{[15]} Parameterized ionization coefficients for GaAs and Al_{0.8}Ga_{0.2}As were taken from Plimmer^{[16]} and Ng,^{[17]} respectively. FIG. 15 shows the calculation of the multiplication for 200 μm diameter mesas. FIG. 15 further shows the measured photocurrent for the GaAs design (), and the AlGaAs design (∘); the modeled multiplication (dotted lines); the calculated primary photocurrent for the GaAs design (▪) and the AlGaAs Design (□); the fitting of the primary photocurrent (solid lines); and the calculated multiplication for the GaAs design (▴) and the AlGaAs design (Δ). As illustrated in FIG. 15, multiplication values could be found accurately from the experimental data, according to the following procedure. Using the modeled multiplication, data for the primary photocurrent was first calculated for all biases. This was expected to depend on the applied voltage, but to be independent of the multiplication itself. The primary photocurrent was found to be well fitted by an exponential function in each case. This was refined by making very small adjustments to the modeled layer profile. These adjustments were cross-checked against the CV data, to ensure good agreement between the two sets of measurements. Finally, the raw photocurrent was divided by the fitted exponentials, giving experimental values for the multiplication.

Excess noise was measured using a calibrated HP 8970B Noise Figure Meter, at frequencies between 20-25 MHz. The device under test was connected using a 50Ω impedance-matched cable. Bias was supplied using a Picosecond 5541 Å Bias Tee. For analysis, it is common for results to be compared with the theoretical predictions of McIntyre.^{[18]} Herein, under the local model, the spectral noise density may be written in terms of the total current, the multiplication and the ratio of the ionization coefficients for electrons and holes, k_{eff}=α/β. This relation can be re-expressed in the well-known form

$$F = {k}_{eff} M + ( 1 - {k}_{eff} ) ( 2 - \frac{1}{M} ) \qquad Equation ( 1 )$$

where F is excess noise and M is the multiplication. In the present work, excess noise results were normalized to the above form using a fitting procedure. This step was necessary in order to correct for the electrical coupling of the device with the meter, which results in a constant factor in the noise values measured. The fitting procedure was verified through measurements on Al_{0.48}In_{0.52}As p-i-n devices, where the electrical coupling can also be found experimentally by measurement of the Shot Noise, as detailed elsewhere.^{[19]} In this analysis, the data in the low M region was disregarded, treating only the data in the near-linear region at high M. This choice becomes important when dead space effects are significant, as is the case for the data for the AlGaAs design. To verify that the approach outlined had produced accurate results, duplicate measurements were made on a range of devices, of various diameters, for both samples.

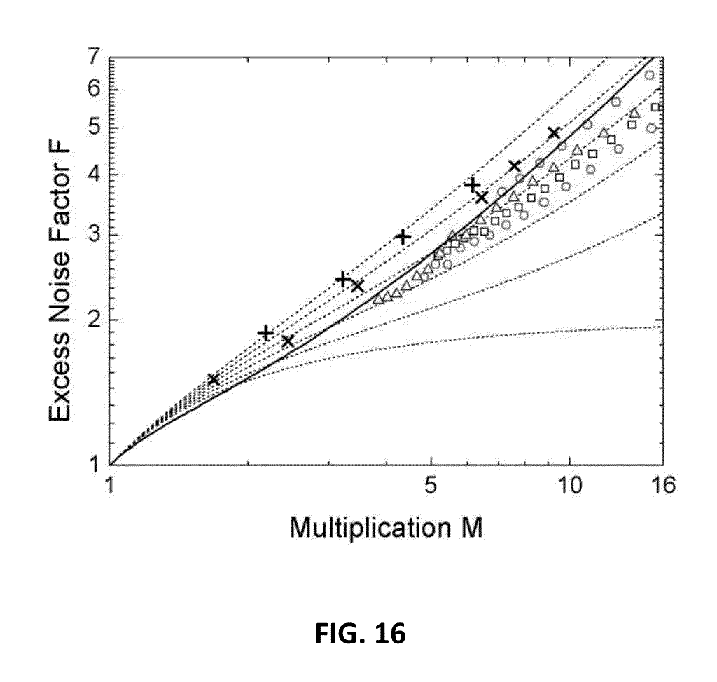

FIG. 16 shows data collected for the GaAs design, which lies in the range 0.2<k_{eff}<0.4. FIG. 16 shows excess noise versus multiplication for a 200 μm diameter device (□), 100 μm diameter devices (∘), a 50 μm diameter device (Δ), an RPL simulation (solid line), a GaAs p-i-n with 0.28 μm intrinsic width [Li, 1998] (x), a GaAs p-i-n with 0.49 μm intrinsic width [Li, 1998] (+), and local model curves of Equation 1, from k=0 to k=0.5, in steps of 0.1 (dashed lines). Previously reported results for thin GaAs p-i-n diodes are also shown.^{[20]} The lower value of k_{eff} apparent in the present devices may be explained based on their higher doping concentration in the multiplication region, so that they approach a p-n design. This results in a localization of the high electric field, and therefore the impact ionization, at the type junction. By decreasing the length over which ionization events are concentrated, the level of disorder and therefore the values of k_{eff} measured are reduced in turn. A random-path-length (RPL) model was used to investigate this effect; results from the model are shown in FIG. 16. The modeled excess noise characteristic can be seen to agree closely with the experimental data. Ionization threshold energies of 2.3 eV for electrons and 2.1 eV for holes were used.^{[20]} The RPL model takes into account a variable field profile, but is otherwise similar to the work of DS Ong.^{[21]}

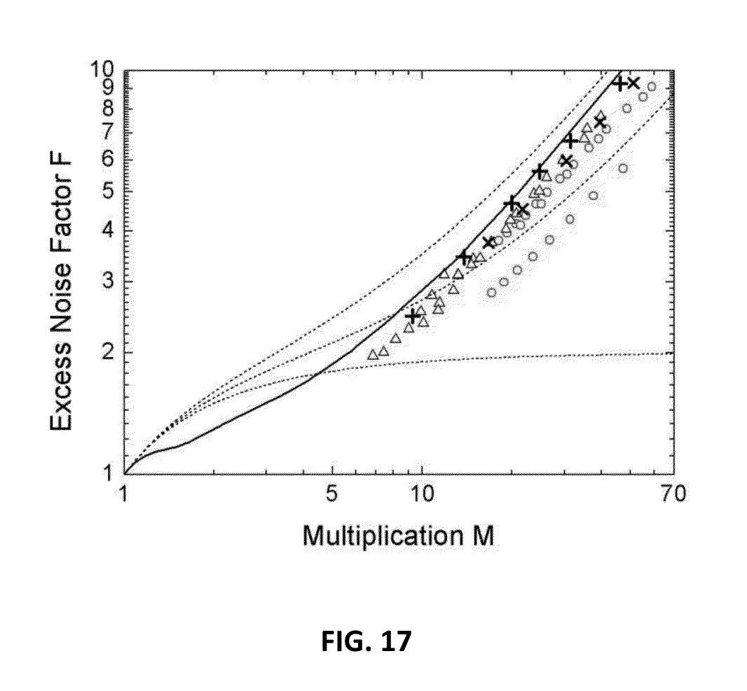

Data collected for the AlGaAs design is shown in FIG. 17. FIG. 17 shows data for 100 μm diameter devices (∘), 50 μm diameter devices (Δ), an RPL simulation (solid line), and Al_{0.8}GaAs p-i-n with 0.03 μm intrinsic width [Ng, 2002] (x), Al_{0.8}GaAs p-i-n with 0.10 μm intrinsic width [Ng, 2002] (+). The dashed lines are the local model curves of Equation 1, from k=0 to k=0.2 in steps of 0.1. This time, a significant deviation from the form of the local model curves can be seen in the region M<20. This effect is attributed to the increased fraction of dead-space in the narrow structure. This is corroborated by an RPL model curve, for which ionization threshold energies of 3.75 eV were used, for both electrons and holes. Except for one outlier, the data was contained in the range 0.1<k_{eff}<0.2. This closely agrees with published data for thin Al_{0.8}Ga_{0.2}As diodes.^{[22]}

At present, only low quantum efficiencies could be obtained in both devices. This is believed to be linked with the band offsets at the GaSb heterojunction and, in the AlGaAs design, additionally with the band offsets at the Al_{0.8}Ga_{0.2}As/GaAs heterojunction. The effects of the GaSb band offset could be mitigated using a doping-interface-dipole approach.^{[23]} Thicker absorption regions and anti-reflective coatings could also be used. Larger photocurrents would also allow correction for the electrical coupling using a Shot Noise measurement, as discussed above.

Two APD structures were demonstrated, each based on a lattice-mismatched GaSb absorber region grown using an IMF array. The first was based on a GaAs design. The second device used an AlGaAs design, allowing for lower noise and dark currents and a thinner multiplication region. Excess noise results were compared with data from similar structures, without long-wavelength absorber regions or mismatched epitaxial interfaces. Agreement was found, indicating an absence of ionization effects associated with the GaSb regions or the interface, which could affect device performance. Comparisons were also made with curves generated using an RPL model, highlighting a dependence on the field profile and dead-space effects. It is envisaged that further designs, based on longer wavelength absorber materials which are lattice-matched to GaSb, could also be developed.

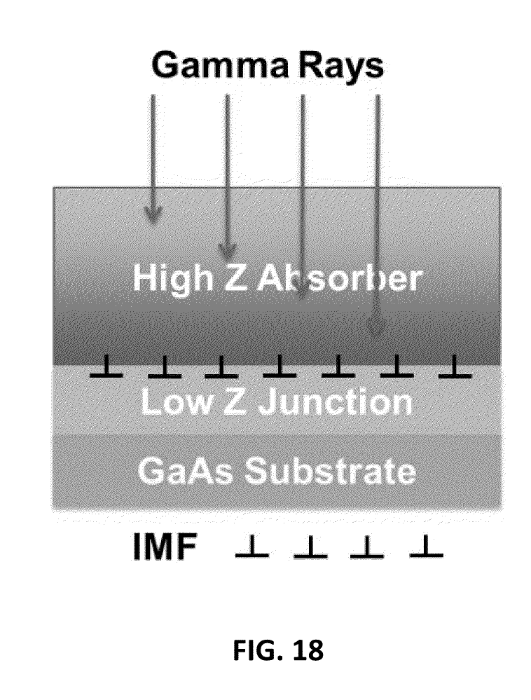

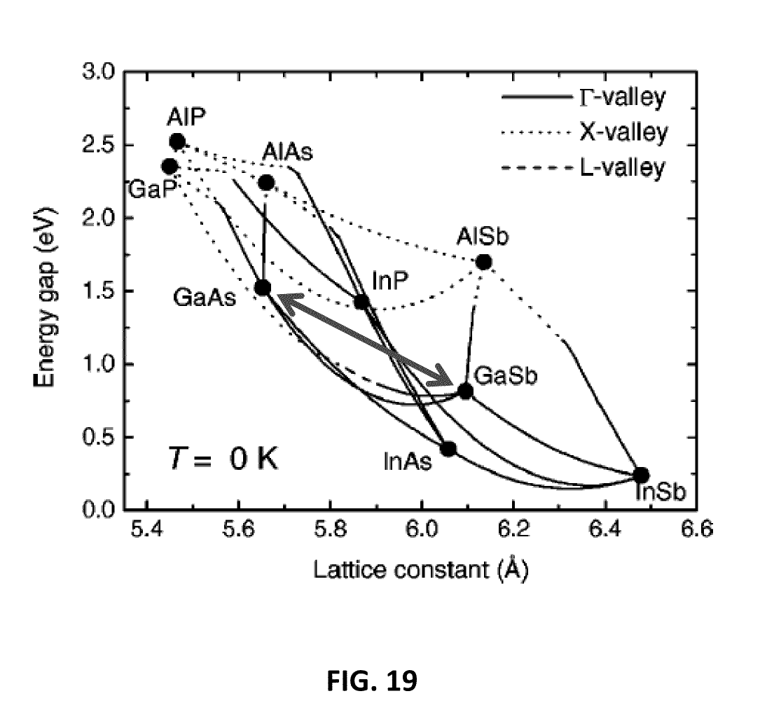

According to some embodiments of the invention, devices are described that enable enhanced detection of gamma rays. The devices employ a novel integration of high atomic number (Z), small bandgap semiconductor absorbers (GaSb or InAsSb) with a low Z, large bandgap junction material ((Al)GaAs), as illustrated in FIG. 18. The absorbers and junction materials have different lattice constants, as shown in FIG. 19. The large strain between the two sections of the device is efficiently managed by creating a nanostructured interfacial misfit (IMF) array. This unique combination of high and low Z materials in a single structure permits increased gamma ray absorption per unit volume, whilst maintaining high signal-to-noise ratio (SNR) carrier extraction. Decoupling the higher stopping power absorber from the junction enhances energy resolution without the cryogenic cooling requirements of state-of-the-art High Purity Germanium (HPGe). The achievable energy resolution of a 662 keV photon in the design is expected to be <0.3% at room temperature, which compares favorably with HPGe (˜0.14% at 77K). Offering high energy resolution and high SNR gamma ray detection at room temperature, these nanostructured devices are highly viable replacements for currently deployed C-WMD sensors.

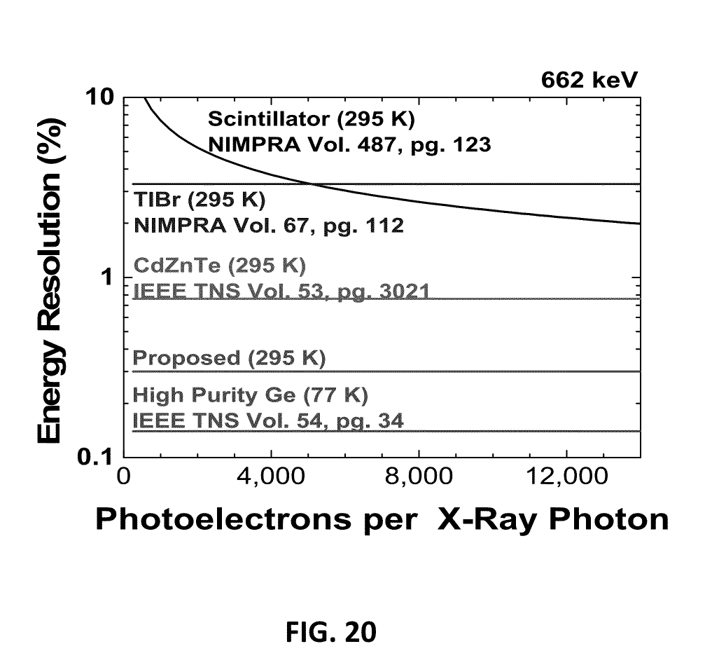

The emission of gamma rays is a signature of certain weapons of mass destruction (WMDs), in particular those posing nuclear and radiological threats. Creating a portable sensor that not only reliably senses the presence of gamma ray emissions but also accurately identifies their energy (therefore providing information about the possible nature of their source) could be a powerful tool for counter-WMD (C-WMD) operations. A detector is designed that combines a high Z absorber with a low Z junction. The theoretical energy resolution of this device is similar to cryogenically cooled HPGe across all photon energies (or more specifically ˜0.14% at 662 keV) and outperforms other competing technologies, as shown in FIG. 20).

The high-energy photon stopping power of a material typically increases with the atomic number Z. High Z compounds are therefore ideally suited to use as gamma ray absorbers. The III-Sb materials (GaSb and InAsSb) chosen for the high Z section of the devices described herein boast some of the largest absorption coefficients for gamma ray photons available within the III-V family of semiconductors. However, low Z materials make significantly better junction and multiplication stages of a detector. The large bandgaps of the III-As materials (GaAs and AlGaAs) chosen for the low Z junction section of the devices lead to high energy resolution. These junction materials have considerably lower leakage currents than GaSb and InAsSb, mainly because of their lower intrinsic carrier concentrations. They can also be used as multiplication regions, allowing for an increased signal strength relative to amplifier noise without generating the spurious signals that have been a problem in the past.

The normally incompatible III-Sb and III-As materials are epitaxially integrated into a monolithic device using a nanostructured interfacial misfit array (IMF). The IMF enables these materials with large differences in both Z and lattice constant to be combined on a common substrate. High strain at the interface between III-Sb and III-As materials typically results in the formation of threading dislocations, negatively impacting both electrical and optoelectronic properties. The nanostructured IMF enables relief of >99.8% of this strain directly at the interface, dramatically reducing the threading dislocation density and ensuring that both the low Z junction and the high Z absorber have excellent crystal quality.

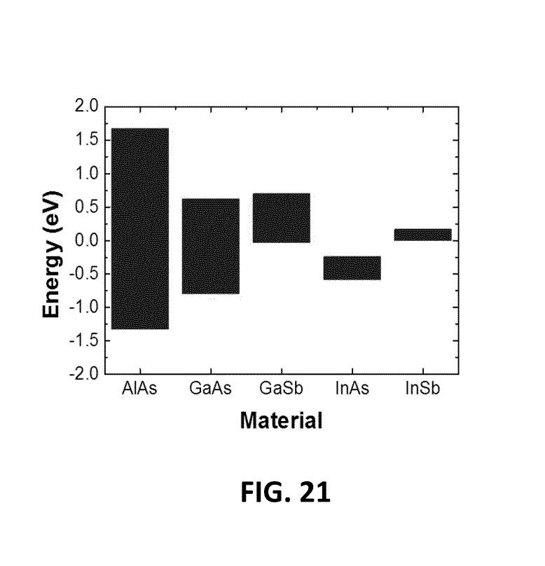

Several device designs are described. Some measurements relate to understanding absorption behavior of the absorber materials GaSb and InAsSb. Since little is currently known about their intrinsic gamma ray absorption properties, high Z GaSb and InAsSb homojunction devices are first fabricated in order to quantify the values for various parameters. These measurements are used in building accurate simulations for subsequent structures and predict which will provide the best achievable resolutions. High Z absorber-low Z junction devices according to some embodiments of the invention feature GaSb as the absorber material, but use GaAs as the large bandgap junction region. High Z absorber-low Z junction devices according to some embodiments of the invention feature GaSb absorbers that are integrated with AlGaAs junctions to offer even larger bandgaps for lower leakage. High Z absorber-low Z junction devices according to additional embodiments of the invention incorporate InAsSb absorbers with the (Al)GaAs junction/multiplication regions. InAsSb absorbers have the highest stopping power and best theoretical energy resolution. The principal issue here is augmenting the charge collection efficiency, as the conduction band discontinuity between AlAs and GaAs, as well as InAsSb and GaSb, are rather large, as shown in FIG. 21. FIG. 21 shows bandgaps and band offsets for materials at 300 K. Values were calculated from Ref [26]. To mitigate this effect, a compositionally graded InGaAsSb buffer may be used.

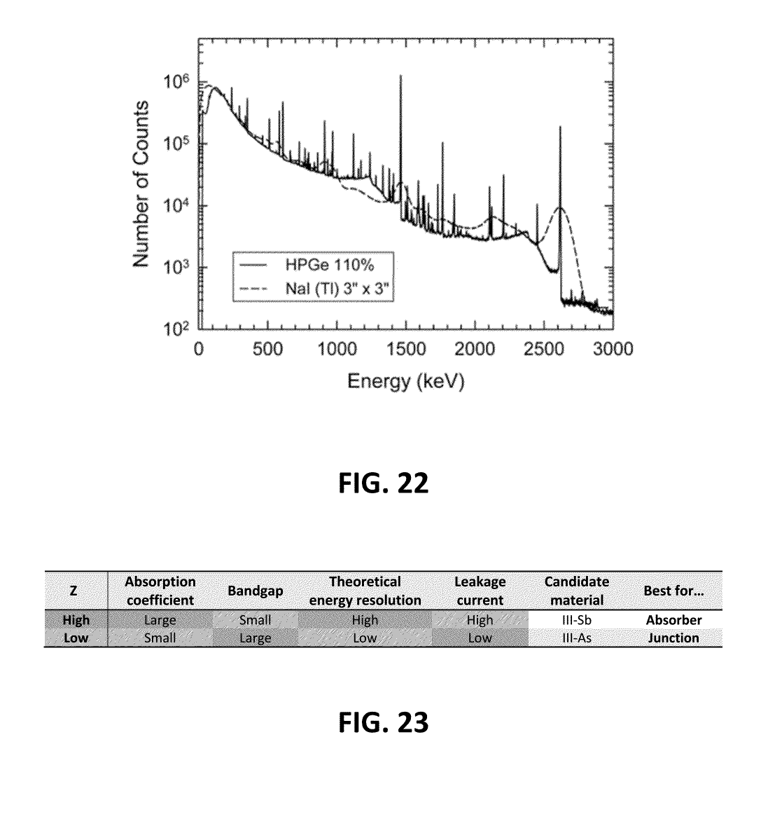

Gamma ray detection is currently based on two entirely different architectures. Most common is the scintillator crystal detector, where a gamma ray photon is converted into multiple low energy photons that can be detected using standard Si or photomultiplier tube (PMT) technology. Although inexpensive, this approach offers limited energy resolution, as shown by the dashed line in FIG. 22, meaning that a scintillator crystal might sense a gamma ray, but precise information about its energy may not be collected. FIG. 22 shows a comparison of gamma ray detectors with high and low energy resolution (HPGe and NaI respectively).^{[24]} For C-WMD applications the limited energy resolution could mean a loss of potentially crucial information about what emitted the gamma ray. The second architecture relies on the direct absorption of a gamma ray photon by the detector material. HPGe, CdZnTe, TlBr, and GaAs are commonly used for this purpose as they have high average Z (30-60) for efficient gamma photon absorption. Small bandgap semiconductors typically make high energy resolution gamma ray detectors, whereas those with large bandgaps are correlated with low energy resolution. But small bandgap materials also suffer from high leakage currents, while in large bandgap materials this noise source is reduced.

FIG. 23 summarizes some of these pros and cons, and effectively illustrates the difficulty with finding a single material that fulfills all the requirements for a C-WMD gamma ray detector. A material that performs well as a junction is likely to make a poor absorber and vice versa. The state-of-the-art gamma ray sensing material HPGe is a good example: although its small bandgap (0.66 eV at 295 K) results in very high energy resolution gamma ray detection (solid line, FIG. 22), cryogenic cooling is required to reduce dark currents associated with the small bandgap. In contrast, larger bandgap CdZnTe, TlBr, and GaAs sensors operate at 300 K, but at the cost of energy resolution. In CdZnTe, TlBr, and GaAs sensors, energy resolution is respectively limited by i) high electron-hole pair creation energy, ii) poor crystal quality, and iii) low absorption coefficients. An obvious need exists in the C-WMD community for a gamma ray detector architecture that addresses all of these deficiencies.

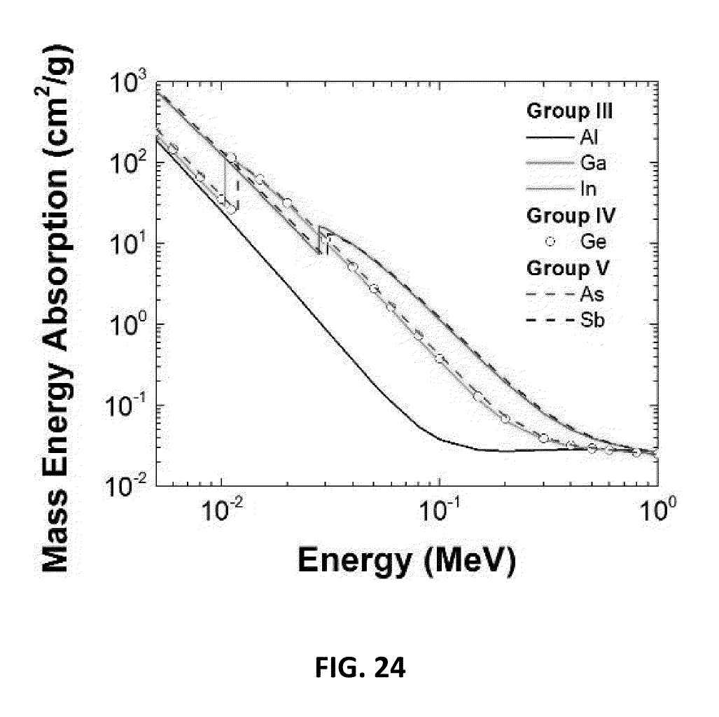

The design described herein overcomes this problem by decoupling the absorption and junction stages of a gamma ray detector (see FIG. 18). By monolithically integrating high and low Z materials of excellent crystal quality, the relative benefits of each are exploited. A high Z, small bandgap III-Sb region provides efficient, high energy resolution gamma ray absorption (see FIG. 24), while a low Z, large bandgap III-As junction offers low noise current extraction at room temperature. FIG. 24 shows photon absorption in selected semiconductor materials at the high energy range important for C-WMD. Historically, structures such as that in FIG. 18 have not been considered because high Z, III-V absorber materials have large lattice constants and are incredibly difficult to incorporate with the smaller lattice constant, larger bandgap III-Vs. The large strain between the mismatched III-Sb and III-As materials seeds threading dislocations that dramatically reduce device performance. However, recent innovations in the development of interfacial misfit (IMF) arrays enable the growth of integrated high Z absorber-low Z junction detector structures such as these for the first time.

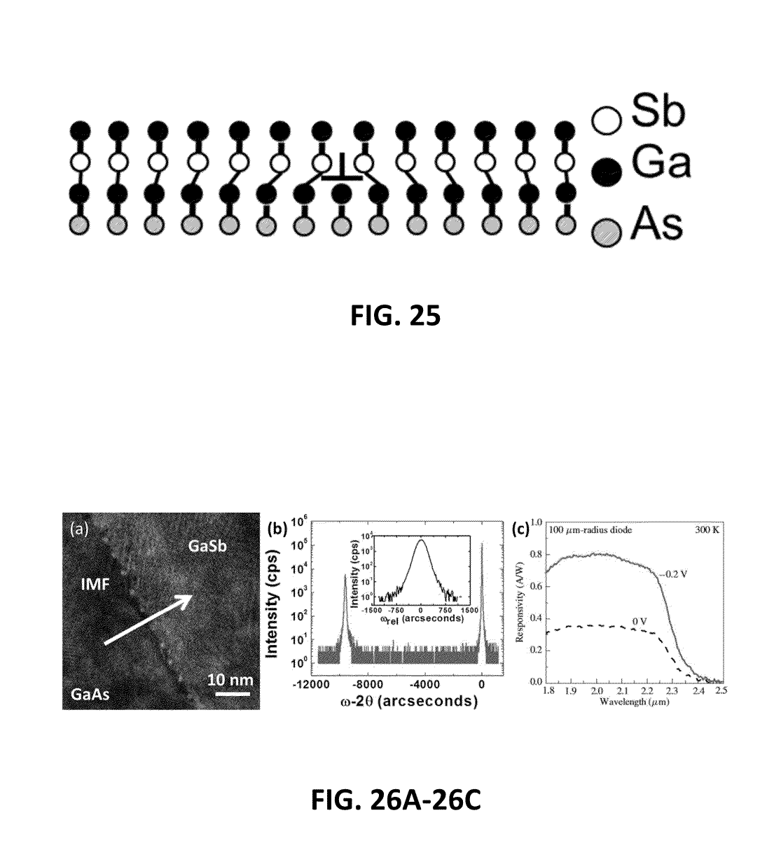

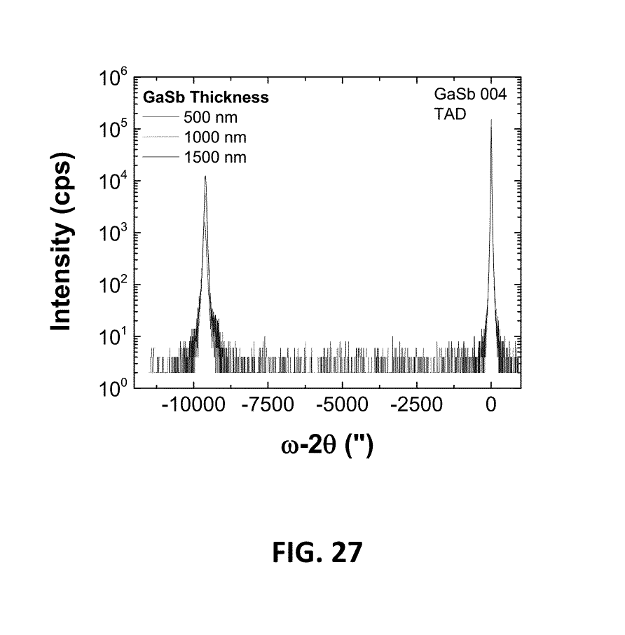

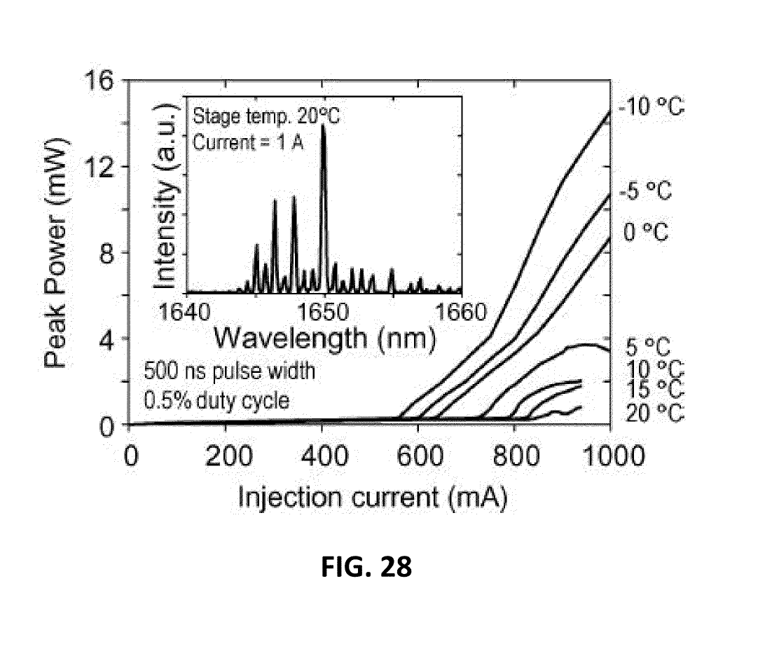

An IMF array is a nanostructured network of 90° Lomer dislocations at the interface between two highly strained materials. A schematic of an IMF array between layers of GaSb and GaAs is shown in FIG. 25. IMFs have been nanoengineered that relieve approximately 99% of the 7.8% strain at the interface between GaSb and GaAs. The IMF technology enables epitaxy of high Z, low electron-hole pair creation energy GaSb with excellent crystal quality directly on large bandgap GaAs. FIG. 26A is an electron microscope image of a GaSb/GaAs interface with an IMF dislocation array (white dots).^{[25]} The dislocations repeat every 5.6 nm and are completely localized at the interface, enabling the growth of defect-free GaSb above the IMF. FIG. 26B shows an 0044 x-ray diffraction scan of a GaSb/GaAs IMF sample. The scan reveals a very narrow epilayer peak, confirming its excellent crystalline quality. The FWHM of the GaSb peak is only 67 arcsec. The inset shows a GaSb peak rocking curve.^{[25]} Indeed, III-Sb detectors grown on IMFs exhibit very high responsivities, as shown in FIG. 26C, and offer comparable performance to identical detectors grown directly on GaSb substrates.^{[28, 29]} FIG. 26C shows the peak responsivity of an IMF-based quaternary Ga_{0.82}In_{0.18}As_{0.16}Sb_{0.84}/GaAs photodiode at 0V and −0.2 V. The peak responsivity of 0.80 Å/W corresponds to an internal quantum efficiency of □74% and, especially considering an estimated depletion width <1 μm, is comparable to some of the best results reported for GaInAsSb diodes grown directly on GaSb substrates.^{[29]} FIG. 27 shows an 0044 x-ray diffraction scan of a GaSb/GaAs IMF sample with varying GaSb thickness. The spacing between the peaks in FIG. 27 indicates an almost completely relaxed material, i.e. no more defects will form. IMF arrays have also been shown to be useful in lasers. FIG. 28 shows peak power versus injection current for room temperature operation of a 1.65 μm laser on a GaAs substrate employing an IMF array. This novel IMF approach provides a reliable GaSb-on-GaAs platform on which to base several alternative gamma ray sensor architectures. The versatility of IMF nanostructuring means AlGaAs junctions can be used with even larger bandgaps for reduced leakage, and lower Z to reduce spurious signals. InAsSb absorbers with very low pair creation energies can be incorporated, and a multiplication region can be built in for avalanche photodiode (APD) operation.

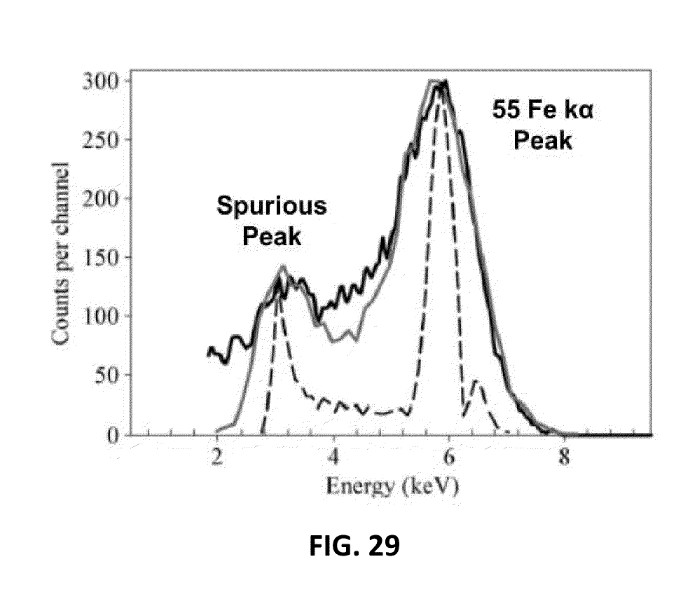

APDs are of distinct interest because they offer dramatically improved SNR in low-energy photon detectors.^{[30]} Preliminary research has also shown that APDs improve energy resolution in x-ray detectors.^{[31]} One issue affecting APDs however is the unwanted collection of carriers outside of the intended absorber region and their subsequent multiplication. Dissimilar multiplication factors in different regions of the APDs result in the output of additional signals for a given photon energy. FIG. 29 shows spurious signal in AlGaAs/GaAs APD detection of a 5.9 keV photon source.^{[27]} Clearly such behavior is extremely undesirable for C-WMD applications. However, this is another situation where the unique decoupled design of the high Z absorber-low Z junction detector comes into its own. In the nanostructured IMF devices according to some embodiments of the invention, the absorber is made from the high absorption coefficient materials GaSb and InAsSb, while the junction consists of low Z (Al)GaAs. This means that very few gamma rays are collected outside of the III-Sb absorber, so diminishing these spurious signals. For the purposes of C-WMD applications this allows the device to sense gamma rays with greatly reduced risk of “false positive” measurements.

The key performance metrics for any gamma ray detector are its external quantum efficiency and its energy resolution. These are defined respectively as the percentage of incident gamma ray photons converted into a detectable signal, and the variation in that signal given a change in the photon energy. The external quantum efficiency can always be increased by adding absorber volume. However, the energy resolution of the system is of greater interest for detection of radioactive decay signatures (such as those from WMDs or “dirty” bombs) and is much more dependent on device architecture. Several factors, strongly dependent on the choice of material system, epitaxial design and device structure, contribute to energy resolution:
1. Fano Factor (f, unitless): A material dependent property of the absorber material that indicates the deviation from pure Poisson statistics in the number of electron-hole pairs per unit photon energy generated. The expected f for a GaSb or InAsSb absorber region is between 0.10-0.14, which is slightly higher but comparable to HPGe's 0.06-0.08.
2. Pair Creation Energy (PCE, eV): A material dependent property of the absorber material that indicates the amount of energy lost by a gamma ray to generate an electron-hole pair. Using semi-empirical models, the expected PCE for a GaSb absorber is 2.83 eV, and for an InAsSb absorber is 2.03 eV. Both values are lower (i.e. better) than the known 2.97 eV for HPGe.
3. APD Multiplication and Noise (M and F, unitless): A material and device dependent property that indicates the amount of multiplication and excess noise generated. The value of F is dependent on multiplication. Studies of F versus energy resolution, photon energy, and multiplication have been performed in scintillator designs, yet very few (if any) exist for solid-state radiation detectors.
4. Ionization Coefficient Ratio (k, unitless): A material and device dependent property indicating the rate at which electrons and holes undergo impact ionization and create gain in the multiplication region. This plays a critical role in the calculation of F. The expected value for our GaAs and AlGaAs designs is in the range of 0.1-0.4.
5. Unintended Multiplication: A device dependent property indicating the extent to which an electron-hole pair created outside the intended absorption region is multiplied, giving rise to an unwanted signal. The mitigation of spurious signals is expected using this design.
6. Charge Collection Efficiency (η, unitless): A material and device dependent property indicating the number of charges collected at the contacts given the number of charges created by the incident gamma ray. Higher charge collection efficiency improves both external quantum efficiency and energy resolution.
7. Dark Current (J, A/cm²): A material and device dependent property indicating the current running through the device in the absence of photocurrent, which raises the noise floor and limits energy resolution. The dark current of the proposed structure is expected to be less than 10⁻⁶ Å/cm².
8. Mass Energy Absorption Coefficient (α, cm⁻¹): A material dependent property of the absorber material that indicates its ability to convert a high energy photon to an electron-hole pair. This value typically scales with Z and density (p). The expected coefficient for GaSb and InAsSb is approximately 50% higher than HPGe.
9. Capacitance (C, nF/cm⁻²): A material and device dependent property that indicates the width of the junction, based on the junction material's DC permittivity. Higher capacitance values increase amplifier noise and limit energy resolution. The expected capacitance for these devices is 10-30 nF/cm⁻², or overall capacitance less than 50 pF.

The listed factors affect each other in various ways, and have specific trends in the III-V materials used. PCE, J, and a are highly dependent on the bandgap. While lower PCE and higher α are better for energy resolution, the lower bandgap increases J exponentially. Meanwhile, lower k is better for multiplication, which favors AlxGal-xAs multiplication regions with aluminum compositions greater than 0.8. However, the conduction band offset increases as well, decreasing collection efficiency η. M, F, and k are also directly related, but their relationship to energy resolution is limited by spurious signal generation.

What is more, the interdependent relationships between the above parameters have been impossible to study previously because of an inability to separate the junction from the absorber. The nanostructured IMF-based design therefore enables the various contributions to be deconvolved from the different parameters, elucidating, for the first time, the actual relationships between them. The mitigation of spurious signals and the associated improvement in energy resolution have important implications for C-WMD. Increased accuracy in the measurement of a collected gamma ray photon's energy with a device operating at or near room temperature enhances the user's ability to identify the nature of its source.

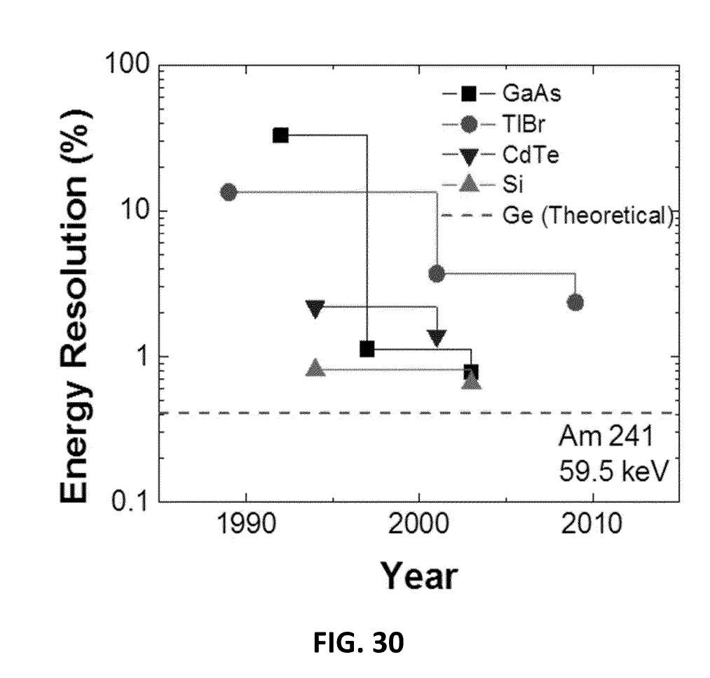

Over the past three decades, GaAs, TlBr, HgI₂, Cd(Zn)Te, and Si based detectors have all been vigorously investigated, almost to the exclusion of other compounds. These materials can be classified into two groups. TlBr, HgI₂ and Cd(Zn)Te are all large bandgap (>1.5 eV) materials with high a. Meanwhile, GaAs and Si are medium bandgap (<1.5 eV) materials with low a. The reason that GaAs and Si have similar energy resolutions to the other materials is that they have extremely mature fabrication technologies, much like HPGe, and hence trapping and mobility problems have largely been engineered away. Because of the mature fabrication technology, these materials have improved more quickly than their large bandgap counterparts, as shown in FIG. 30. However, they cannot be used in place of HPGe because of their low mass energy absorption. FIG. 30 shows improvements by year in energy resolution for a 59.5 keV photon. Note that these represent the best absolute numbers, and device parameters such as shaping time, operating temperature, and size are not fixed.

The III-Sb materials offer a potential solution. The antimonides offer high a and more mature fabrication technologies than the large bandgap materials. However, antimonides have historically suffered from other challenges including surface Fermi-level pinning in the valence band, poor substrate quality, and high background doping concentrations. The use of IMF technology allows for all of these challenges to be met.

The detectors according to some embodiments of the invention include monolithic integration of a high Z absorber and low Z junction. Since the absorber materials have small bandgaps, they typically have high intrinsic carrier concentrations and high leakage currents. Using a standard semiconductor radiation detector design—either a rectifying junction or drift field—would be detrimental to energy resolution as the dark current noise would be orders of magnitude higher than the Fano noise. This is solved in the nanostructured IMF-based devices by moving the high electric field from the high Z, small bandgap absorber, and into the low Z, large bandgap junction. In this way, it is possible to limit the leakage originating from the small bandgap, high Z absorber region, while small drift currents and diffusion currents successfully extract carriers. Complementary modeling of the charge collection efficiency and dark current of such a design enables new designs based on mature III-V technology.

According to some embodiments of the invention, multiplication gain is introduced to a monolithic x-ray detector. Multiplication gain is well understood in scintillator designs, and to some extent solid state designs, but has never been explored across such a large range of energies as those required for C-WMD applications. A fundamental study of energy resolution versus multiplication builds upon previous work in GaAs, and the introduction of an AlGaAs multiplication region further elucidates the role of excess noise (F) on energy resolution.

Second order effects in such a novel architecture must also be understood. The roles of multiplication, absorption in the substrate, and Compton backscattering in spurious peak generation can all be isolated. The large difference in Z between the junction and the absorber, and the introduction of a semi-insulating substrate help to resolve these roles. Meanwhile, Compton backscattering from the substrate is also determined experimentally by removing the substrate, using an AlGaAs selective etch and lift-off technique. This technique is made possible by using an IMF-based approach.

### REFERENCES

[1] I. M. Baker, S. S. Duncan and J. W. Copley, in Proc. SPIE 5406, 133 (2004).
[2] A. Krier and W. Suleiman, Appl. Phys. Lett. 89, 083512 (2006).
[3] A. R. J. Marshall, C. H. Tan, M. J. Steer, and J. P. R. David, Appl. Phys. Lett. 93, 111107 (2008).
[3b] A. R. J. Marshall, C. H. Tan, M. J. Steer, and J. P. R. David, IEEE Photonics Technol. Lett. 21, 13, 866 (2009).
[4] S. Mallick, K. Banerjee, S. Ghosha, E. Plis, J. B. Rodriguez, S. Krishna and C. Grein, Appl. Phys. Lett. 91, 241111 (2007).
[5] Y. L. Goh, D. S. G. Ong, S. Zhang, J. S. Ng, C. H. Tan and J. P. R. David, in IEEE Lasers and Electro-Optics Society, LEOS Annual Meeting Conference Proceedings 2009, 4-8 Oct. 2009, pp. 293-294.
[6] E. K. Duerr, M. J. Manfra, M. A. Diagne, R. J. Bailey, J. P. Donnelly, M. K. Connors, and G. W. Turner, Appl. Phys. Lett. 91, 231115 (2007).
[7] 0. V. Sulima, M. G. Mauk, Z. A. Shellenbarger, J. A. Cox, J. V. Li, P. E. Sims, S. Datta and S. B. Rafol, in IEE Proceedings—Optoelectronics, Volume 151, 1, February 2004, p. 1-5.
[8] S. H. Huang, G. Balakrishnan, A. Khoshakhlagh, A. Jallipalli, L. R. Dawson, and D. L. Huffaker, Appl. Phys. Lett. 88, 131911 (2006).
[9] S. Huang, G. Balakrishnan, and D. L. Huffaker, J. Appl. Phys. 105, 103104 (2009).
[10] M. Mehta, G. Balakrishnan, S. Huang, A. Khoshakhlagh, A. Jallipalli, P. Patel, M. N. Kutty, L. R. Dawson, and D. L. Huffaker, Appl. Phys. Lett. 89, 211110 (2006).
[11] J. B. Rodriguez, L. Cerutti, and E. Tournié, Appl. Phys. Lett. 94, 023506 (2009).
[12] K. C. Nunna, S. L. Tan, C. J. Reyner, A. R. J. Marshall, B. Liang, A. Jallipalli, J. P. R. David, and D. L. Huffaker, IEEE Photonics Technol. Lett. 24, 3 (2012).
[13] A. Jallipalli, K. Nunna, M. N. Kutty, G. Balakrishnan, G. B. Lush, L. R. Dawson, and D. L. Huffaker, Appl. Phys. Lett. 95, 072109 (2009).
[14] S. Sridaran, A. Chavan and P. S. Dutta, J. Cryst. Growth 310, 1590 (2008).
[15] G. E. Stillman and C. M. Wolfe, “Avalanche Photodiodes,” in Infrared Detectors II, R. K. Willardson and A. C. Beer, Eds., vol. 12 of Semiconductors and Semimetals, pp. 291-393. Academic Press, New York 1977.
[16] S. A. Plimmer, J. P. R. David, and D. S. Ong, IEEE Trans. Electron Devices 47, 5 (2000).
[17] B. K. Ng, J. P. R. David, S. A. Plimmer, M. Hopkinson, R. C. Tozer, and G. J. Rees, Appl. Phys. Lett, 77, 26, 4374 (2000).
[18] R. J. McIntyre IEEE Trans. Electron Devices 13, 1, 164 (1966).
[19] J. C. Campbell, S. Chandraskhar, W. T. Tsang, G. J. Qua and B. C. Johnson, Journal of Lightwave Technology 7, 3, 473 (1989).
[20] K. F. Li, D. S. Ong, J. P. R. David, G. J. Rees, R. C. Tozer, P. N. Robson, and R. Grey, IEEE Trans. Electron. Devices 45, 10, 2102 (1998).
[21] D. S. Ong, K. F. Li, G. J. Rees, J. P. R. David, and P. N. Robson, J. Appl. Phys. 83, 6, 3426 (1998).
[22] B. K. Ng, J. P. R. David, R. C. Tozer, M. Hopkinson, G. Hill, and G. J. Rees, IEEE Photonics Technol. Lett. 14, 4, 522 (2002).
[23] F. Capasso, A. Y. Cho, K. Mohammed and P. W. Foy, Appl. Phys. Lett. 46, 7, 664 (1985).
[24] B. D. Milbrath, A. J. Peurrung, M. Bliss, and W. J. Weber, “Radiation detector materials: An overview,” Journal of Materials Research, vol. 23, pp. 2561-2581, 2008.
[25] C. J. Reyner, J. Wang, K. Nunna, A. Lin, B. Liang, M. S. Goorsky, and D. L. Huffaker, “Characterization of GaSb/GaAs interfacial misfit arrays using x-ray diffraction,” Applied Physics Letters, vol. 99, p. 231906, 2011.
[26] I. Vurgaftman, J. R. Meyer, and L. R. Ram-Mohan, “Band parameters for III-V compound semiconductors and their alloys,” Journal of Applied Physics, vol. 89, pp. 5815-5875, 2001.
[27] R. B. Gomes, T. Chee Hing, J. E. Lees, J. P. R. David, and N. Jo Shien, “Effects of Dead Space on Avalanche Gain Distribution of X-Ray Avalanche Photodiodes,” Electron Devices, IEEE Transactions on, vol. 59, pp. 1063-1067, 2012.
[28] E. Plis, J. B. Rodriguez, G. Balakrishnan, Y. D. Sharma, H. S. Kim, T. Rotter, and S. Krishna, “Mid-infrared InAs/GaSb strained layer superlattice detectors with nBn design grown on a GaAs substrate,” Semiconductor Science and Technology, vol. 25, p. 085010, 2010.
[29] K. C. Nunna, T. Siew Li, C. J. Reyner, A. R. J. Marshall, L. Baolai, A. Jallipalli, J. P. R. David, and D. L. Huffaker, “Short-Wave Infrared GaInAsSb Photodiodes Grown on GaAs Substrate by Interfacial Misfit Array Technique,” Photonics Technology Letters, IEEE, vol. 24, pp. 218-220, 2012.
[30] S. M. Sze, Physics of Semiconductor Devices. New York: John Wiley & Sons.
[31] R. Farrell, K. Vanderpuye, G. Entine, and M. R. Squillante, “High resolution, low energy avalanche photodiode X-ray detectors,” Nuclear Science, IEEE Transactions on, vol. 38, pp. 144-147, 1991.

The embodiments illustrated and discussed in this specification are intended only to teach those skilled in the art how to make and use the invention. In describing embodiments of the invention, specific terminology is employed for the sake of clarity. However, the invention is not intended to be limited to the specific terminology so selected. The above-described embodiments of the invention may be modified or varied, without departing from the invention, as appreciated by those skilled in the art in light of the above teachings. It is therefore to be understood that, within the scope of the claims and their equivalents, the invention may be practiced otherwise than as specifically described.

We claim:

1. An avalanche photodiode, comprising:
a first electrode;
a second electrode spaced apart from said first electrode;
a photon absorber layer formed to be in electrical connection with said first electrode; and
a charge-carrier multiplication layer formed to be in electrical connection with said second electrode,
wherein said photon absorber layer is a semiconducting material that has a first lattice constant,
wherein said charge-carrier multiplication layer is a semiconducting material that has a second lattice constant that is different from said first lattice constant,
wherein said photon absorber layer and said charge-carrier multiplication layer are connected together by an interfacial misfit (IMF) array at an interface thereof such that said IMF array provides at least part of an acceleration potential for an avalanche region of said avalanche photodiode.

2. An avalanche photodiode according to claim 1, wherein said avalanche region has a high electric field, and wherein said IMF array confines said high electric field within the multiplication region.

3. An avalanche photodiode according to claim 1, wherein said charge-carrier multiplication layer further comprises a delta doped region to act in combination with said IMF array for providing a field that improves quantum efficiency.

4. An avalanche photodiode according to claim 3, wherein said IMF array has a first two-dimensional charge density of a first polarity, and wherein said delta doped region has a second two-dimensional charge density of a second polarity.

5. An avalanche photodiode according to claim 4, wherein said second two-dimensional charge density is a maximum of 25% of said first two-dimensional charge density times.

6. An avalanche photodiode according to claim 1, wherein said charge-carrier multiplication layer has a charge carrier doping concentration that is less than 5×10¹⁷ cm⁻³.

7. An avalanche photodiode according to claim 3, wherein said delta doped region is spaced apart from said IMF array, and wherein a distance between said delta doped region and said IMF array is less than 30 nm.

8. An avalanche photodiode according to claim 1, wherein said multiplication layer comprises at least one of silicon, GaAs, AlGaAs, InP, InAlAs, or InAlGaAs.

9. An avalanche photodiode according to claim 1, wherein said photon absorber layer comprises at least one of GaSb, InAsSb, InGaAsSb.

10. An avalanche photodiode according to claim 1, wherein said photon absorber layer comprises a material having a composition according to In(x)Ga(1-x)As(y)Sb(1-y).

11. An avalanche photodiode according to claim 1, wherein said photon absorber layer comprises a material having a lattice constant that is 6-6.2 Å.

12. An avalanche photodiode according to claim 3, wherein said delta doped region comprises at least one of silicon, zinc, hydrogen, boron, phosphorus, tellurium, beryllium, arsenic, or carbon.

13. An avalanche photodiode according to claim 1, wherein said multiplication layer comprises an undoped region and a lightly doped region.

14. An avalanche photodiode according to of claim 1, wherein said photon absorber layer comprises a first doped region proximate said IMF array and a second doped region farther from said IMF array than said first doped region, said second doped region having a greater doping concentration than said first doped region.

15. An avalanche photodiode according to of claim 14, wherein said first doped region proximate said IMF array and said second doped region farther from said IMF array than said first doped region are doped with a same type of charge carrier.

16. A high energy or low energy photon gamma ray detector comprising:
an avalanche photodiode, comprising:
a first electrode;
a second electrode spaced apart from said first electrode;
a photon absorber layer formed to be in electrical connection with said first electrode; and
a charge-carrier multiplication layer formed to be in electrical connection with said second electrode,
wherein said photon absorber layer is a semiconducting material that has a first lattice constant,
wherein said charge-carrier multiplication layer is a semiconducting material that has a second lattice constant that is different from said first lattice constant,
wherein said photon absorber layer and said charge-carrier multiplication layer are connected together by an interfacial misfit (IMF) array at an interface thereof such that said IMF array provides at least part of an acceleration potential for an avalanche region of said avalanche photodiode.

17. A method for forming an avalanche photodiode, comprising:
selecting a substrate;
depositing a buffer layer on said substrate;
depositing on said buffer layer a first contact and a charge-carrier multiplication layer;
forming on said charge-carrier multiplication layer an interfacial misfit (IMF) array;
depositing on said IMF array a photon absorber layer;
depositing on said photon absorber layer a second contact,
wherein said substrate, said buffer layer, and said charge-carrier multiplication layer have a first lattice constant, and wherein said photon absorber layer has a second lattice constant that is different from said first lattice constant, and
wherein said avalanche photodiode is formed in a single fabrication process.

18. A method for forming an avalanche photodiode according to claim 17, wherein said IMF array provides at least part of an acceleration potential for an avalanche region of said avalanche photodiode.

19. A method for forming an avalanche photodiode according to claim 17, where the avalanche photodiode is formed using molecular beam epitaxy (MBE).

20. A method for forming an avalanche photodiode according to claim 17, wherein depositing said charge-carrier multiplication layer further comprises depositing a first layer that is lightly doped and a second layer that is undoped.

21. A method for forming an avalanche photodiode according to claim 20, further comprising:
exposing said first layer that is lightly doped to a delta doping material to form a delta doped region on said first layer; and
depositing a said second layer that is undoped on said delta doped region.

22. A method for forming an avalanche photodiode according to claim 21, wherein said IMF array has a first two-dimensional charge density of a first polarity, and wherein said delta doped region has a second two-dimensional charge density of a second polarity, wherein said second two-dimensional charge density is a maximum of 25% of said first two-dimensional charge density.

23. An avalanche photo diode produced according to claim 17.
